(19) United States
(12) Patent Application Publication
(10) Pub. No.: US 2021/0069861 A1
(43) Pub. Date: Mar. 11, 2021

(54) GRINDING APPARATUS AND GRINDING METHOD

(71) Applicant: Kioxia Corporation, Minato-ku (JP)

(72) Inventors: Takahiko KAWASAKI, Yokohama (JP); Kazufumi NOMURA, Yokkaichi (JP)

(73) Assignee: Kioxia Corporation, Minato-ku (JP)

(21) Appl. No.: 16/814,764

(22) Filed: Mar. 10, 2020

(30) Foreign Application Priority Data
Sep. 9, 2019 (JP) 2019-163965

(51) Int. Cl. B24B 53/053; B24B 51/00

(52) U.S. Cl. CPC B24B 53/053; B24B 51/00

(57) ABSTRACT

A grinding apparatus according to an embodiment comprises: a table to hold a substrate; a grinding stone driver to be rotatable while holding a grinding stone; and a location adjuster to adjust a relative location between the grinding stone driver and the table. The grinding stone has steps including a first grinding face and a second grinding face, and a first distance between a rotation center of the grinding stone driver and the first grinding face is different from a second distance between the rotation center and the second grinding face. The location adjuster adjusts the relative location from a first state in which the first grinding face is in contact with an end face of the substrate to a second state in which the second grinding face is in contact with the end face.

### CROSS-REFERENCE TO RELATED APPLICATIONS

This application is based upon and claims the benefit of priority from Japanese Patent Application No. 2019-163965, filed on Sep. 9, 2019; the entire contents of which are incorporated herein by reference.

### FIELD

Embodiments of the present invention relate to a grinding apparatus and a grinding method.

### BACKGROUND

One of processes for processing a substrate (a wafer) is trimming processing in which an end face (a wafer edge) of the substrate is ground with a grinding stone. Associated with the trimming processing, uneven abrasion occurs where the grinding stone deforms locally. Accordingly, dressing is performed to correct the uneven abrasion on the grinding stone.

### BRIEF DESCRIPTION OF THE DRAWINGS

FIG. 1 is a schematic diagram illustrating a schematic configuration of a grinding apparatus according to a first embodiment;

FIG. 2A is a schematic diagram of a grinding wheel according to the first embodiment;

FIG. 2B is a schematic diagram of a grinding wheel according to a modification;

FIG. 3A is a diagram enlargedly illustrating a periphery of a location adjuster;

FIG. 3B is a plan view of FIG. 3A;

FIG. 4 is a flowchart for explaining a grinding operation of the grinding apparatus according to the first embodiment;

FIG. 5A is a diagram for explaining trimming processing;

FIG. 5B is a diagram for explaining the trimming processing;

FIG. 6 is a schematic diagram illustrating a schematic configuration of a grinding apparatus according to a second embodiment;

FIG. 7 is a top view of the grinding apparatus illustrated in FIG. 6;

FIG. 8 is a flowchart for explaining a dressing operation of the grinding apparatus according to the second embodiment;

FIG. 9 is a diagram for explaining dressing;

FIG. 10A is a diagram illustrating a state of a grinding stone part at an initial stage of the dressing;

FIG. 10B is a diagram illustrating a state of the grinding stone part at a last stage of the dressing; and

FIG. 11 is a graph illustrating changes of a drive current required to drive a dressing grinding stone.

### DETAILED DESCRIPTION

Embodiments will now be explained with reference to the accompanying drawings. The present invention is not limited to the embodiments.

A grinding apparatus according to an embodiment comprises: a table to hold a substrate; a grinding stone driver to be rotatable while holding a grinding stone; and a location adjuster to adjust a relative location between the grinding stone driver and the table. The grinding stone has steps including a first grinding face and a second grinding face, and a first distance between a rotation center of the grinding stone driver and the first grinding face is different from a second distance between the rotation center and the second grinding face. The location adjuster adjusts the relative location from a first state in which the first grinding face is in contact with an end face of the substrate to a second state in which the second grinding face is in contact with the end face.

### First Embodiment

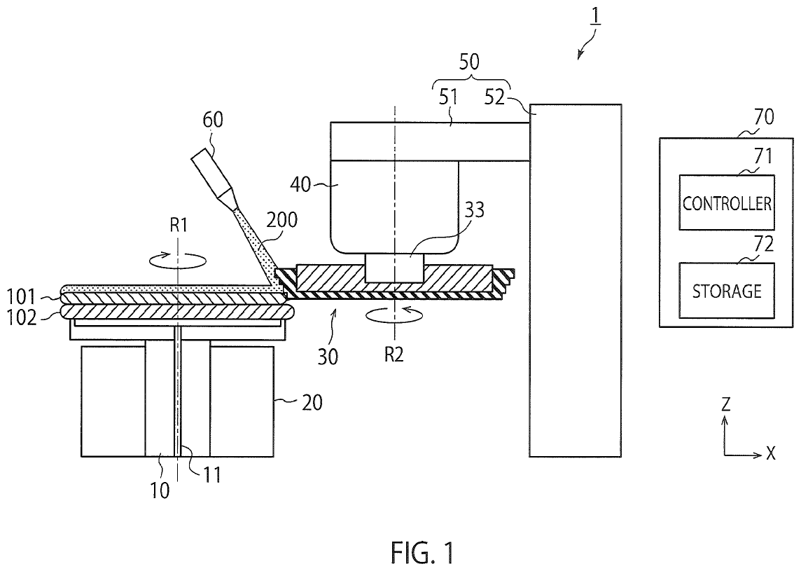

FIG. 1 is a schematic diagram illustrating a schematic configuration of a grinding apparatus according to a first embodiment. A grinding apparatus 1 illustrated in FIG. 1 includes a table 10, a table driver 20, a grinding wheel 30, a grinding stone driver 40, a location adjuster 50, a nozzle 60, and a terminal 70.

A vacuum chuck 11 is provided on the table 10. A substrate 101 and a substrate 102 are held on the table 10 by the vacuum chuck 11. The substrate 101 and the substrate 102 are silicon wafers bonded to each other. For example, a three-dimensional semiconductor memory on which word lines are stacked is formed on the substrate 101 being a grinding target. Meanwhile, for example, a driving circuit that drives the three-dimensional semiconductor memory on the substrate 101 is formed on the substrate 102. Although the two substrates are held on the table 10 in the present embodiment, one substrate may be held thereon.

The table driver 20 is coupled to a lower part of the table 10. The table driver 20 includes, for example, a motor that rotates the table 10 in a rotation direction R1 on the basis of control of the terminal 70, a driving circuit for the motor, and the like.

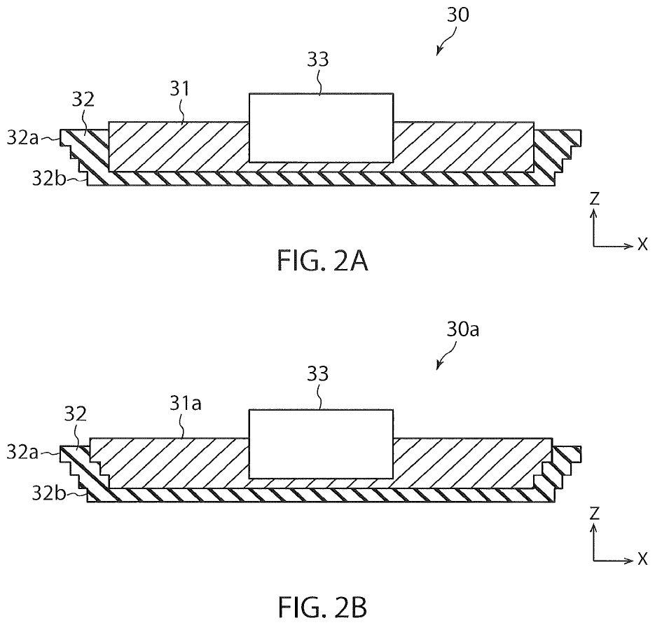

The grinding wheel 30 that grinds the end face of the substrate 101 is placed on the outer side of the table 10. Configurations of the grinding wheel 30 are explained below with reference to FIGS. 2A and 2B.

FIG. 2A is a schematic diagram of the grinding wheel 30 according to the present embodiment. As illustrated in FIG. 2A, the grinding wheel 30 includes a core 31, a grinding stone part 32, and a rotation shaft 33. The core 31 is a metallic member such as stainless steel or aluminum. The rotation shaft 33 is fixed to a central part of the core 31.

The grinding stone part 32 is coupled to a surface of the core 31. The grinding stone part 32 contains many abrasive grains, and a bond material that couples the abrasive grains to each other. The material of the abrasive grains is, for example, natural diamond or synthetic diamond. The material of the bond material is, for example, resin, vitrified, or metal. The abrasive grains and the bond material may be formed by electrodeposition (plating) processing to the surface of the core 31. The outer circumference of the grinding stone part 32 is formed in a stepped shape. Steps on the outer circumference have a shape inclined obliquely downward from a grinding face 32a of the top step toward a grinding face 32b of the bottom step. That is, the distance between the end face of the grinding face 32a of the top step and the rotation center of the grinding stone part 32 is larger than the distance between the end face of the grinding face 32b of the bottom step and the rotation center. The number of steps formed on the outer circumference of the grinding stone part 32 is not particularly limited.

FIG. 2B is a schematic diagram of a grinding wheel according to a modification. In a grinding wheel 30a illustrated in FIG. 2B, the outer circumference of a core 31a is also formed in a stepped shape identical to that of the grinding wheel 32.

The rotation shaft 33 is a spindle coupled to the grinding stone driver 40. The grinding stone driver 40 is coupled to the rotation shaft 33 as illustrated in FIG. 1.

The grinding stone driver 40 includes, for example, a motor that rotates the grinding wheel 30 in a rotation direction R2 opposite to the rotation direction R1 of the table 10 on the basis of control of the terminal 70, a driving circuit for the motor, and the like. The grinding stone driver 40 may rotate the grinding wheel 30 in the same direction as the rotation direction R1. The location adjuster 50 that adjusts the location of the grinding wheel 30 is coupled to the grinding stone driver 40.

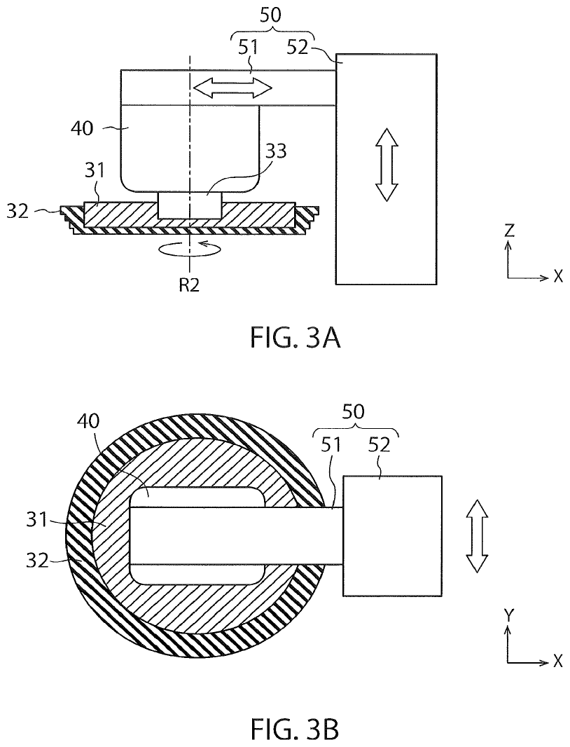

FIG. 3A is a diagram enlargedly illustrating a periphery of the location adjuster 50. FIG. 3B is a plan view of FIG. 3A. As illustrated in FIGS. 3A and 3B, the location adjuster 50 includes an arm 51 coupled to the grinding stone driver 40, and a lift 52 that supports the arm 51.

The arm 51 adjusts the locations in an X direction and a Y direction of the grinding wheel 30. The X direction and the Y direction are directions parallel to the substrate 101 and orthogonal to each other. The lift 52 adjusts the location in a Z direction of the grinding wheel 30. The Z direction is a direction orthogonal to the X direction and the Y direction.

As illustrated in FIG. 1, the nozzle 60 is provided above the table 10. The nozzle 60 ejects pure water 200 toward a grinding place where the substrate 101 and the grinding stone part 32 are in contact with each other, on the basis of control of the terminal 70. The grinding place is cooled with the pure water 200. Further, scraps generated by a trimming process described later can be rinsed off by the ejection of the pure water 200.

The terminal 70 includes a controller 71 and a storage 72. The controller 71 controls trimming processing of grinding the end face of the substrate 101 with the grinding wheel 30. The storage 72 stores therein various data such as an operation program of the controller 71 and location information of the grinding wheel 30. The terminal 70 is not a constituent element of the grinding apparatus 1 and may be provided outside the apparatus.

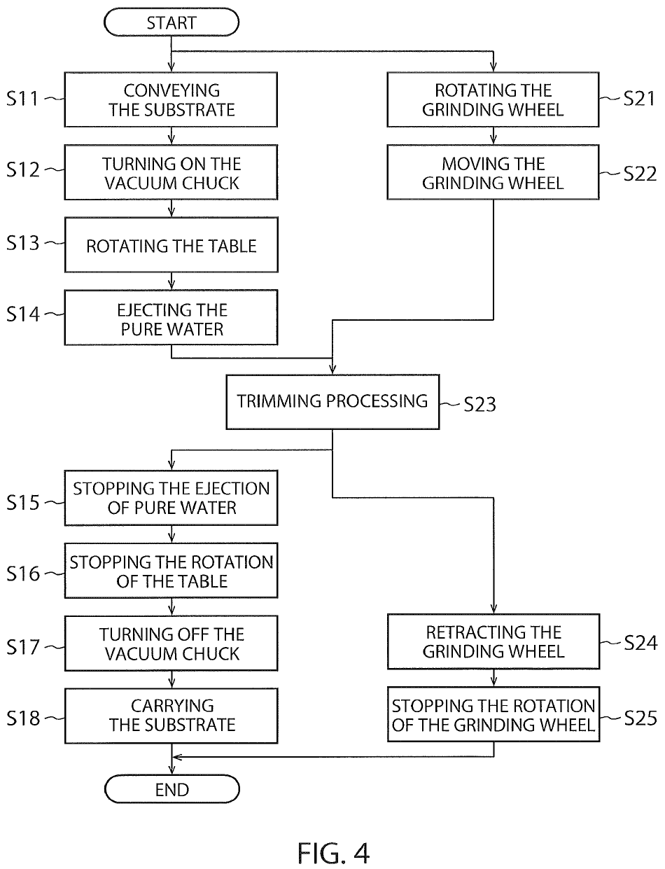

A grinding operation of the grinding apparatus 1 described above is explained below with reference to FIG. 4. FIG. 4 is a flowchart for explaining a grinding operation of the grinding apparatus 1 according to the first embodiment.

First, on the substrate side, a conveyer mechanism (not illustrated) conveys the substrate 101 and the substrate 102 which are bonded to each other onto the table 10 on the basis of an instruction of the controller 71 of the terminal 70 (Step S11). Next, the vacuum chuck 11 is turned ON on the basis of an instruction of the controller 71 (Step S12). Accordingly, the substrate 101 and the substrate 102 are fixed to the table 10.

Next, the table driver 20 rotates the table 10 on the basis of an instruction of the controller 71 (Step S13). Accordingly, the substrate 101 and the substrate 102 which are fixed to the table 10 are also rotated. Subsequently, the nozzle 60 ejects the pure water 200 on the basis of an instruction of the controller 71 (Step S14).

Meanwhile, on the grinding stone side, the grinding stone driver 40 rotates the grinding wheel 30 on the basis of an instruction of the controller 71 (Step S21), in parallel to the operation at Step S11. Next, the location adjuster 50 moves the grinding wheel 30 to a location where the grinding wheel 30 is in contact with the end face of the substrate 101 (Step S22). Accordingly, the trimming processing of grinding the end face of the substrate 101 with the grinding wheel 30 is performed.

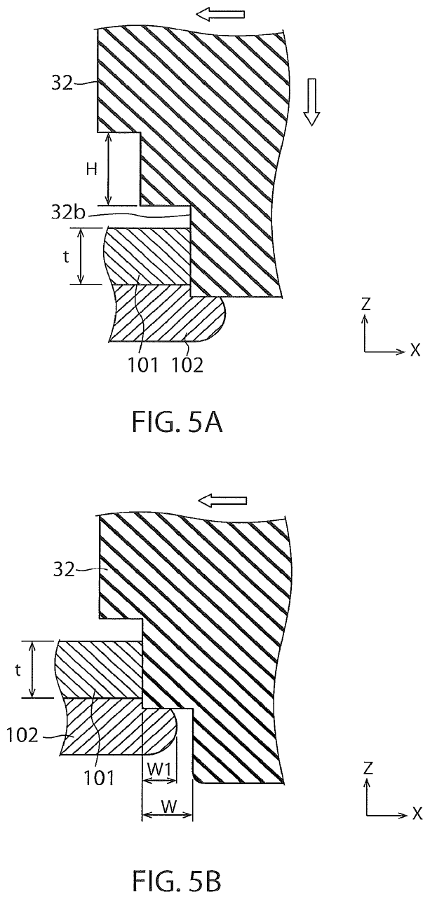

FIGS. 5A and 5B are both diagrams for explaining the trimming processing. In the trimming processing, the location adjuster 50 first moves the grinding wheel 30 in the X direction to bring the grinding face 32b of the bottom step among the steps formed on the outer circumference of the grinding stone part 32 into contact with the end face of the substrate 101 as illustrated in FIG. 5A. Subsequently, the end face of the substrate 101 is ground with the grinding face 32b of the bottom step.

When a predetermined time thereafter passes or when the number of ground substrates 101 reaches a predetermined value, the location adjuster 50 lowers the grinding wheel 30 in the Z direction to move the grinding wheel 30 to a location illustrated in FIG. 5B. In FIG. 5B, a grinding face of a step just above the grinding face 32b of the bottom step is in contact with the end face of the substrate 101. A height H of each of grinding faces of the steps formed on the grinding stone part 32 is larger than a thickness t of the substrate 101 being the grinding target. A width W of each step is larger than a cutting width W1 in view of a dimension margin. Therefore, with the stepwise lowering of the grinding wheel 30 by the location adjuster 50, the end face of the substrate 101 is ground step by step with the grinding face of the grinding stone part 32.

When the trimming processing described above ends, the nozzle 60 stops the ejection of pure water 200 on the basis of an instruction of the controller 71 (Step S15). Next, the table driver 20 stops the rotation of the table 10 on the basis of an instruction of the controller 71 (Step S16). Accordingly, the rotation of the substrate 101 and the substrate 102 is also stopped.

Next, the vacuum chuck 11 is turned OFF on the basis of an instruction of the controller 71 (Step S17). Finally, the conveyer mechanism (not illustrated) carries the substrate 101 and the substrate 102 held on the table 10 on the basis of an instruction of the controller 71 (Step S18).

Meanwhile, on the grinding stone side, the location adjuster 50 retracts the grinding wheel 30 from the substrate 101 on the basis of an instruction of the controller 71 (Step S24), in parallel to the operation at Step S15. Finally, the grinding stone driver 40 stops the rotation of the grinding wheel 30 (Step S25).

According to the present embodiment explained above, the outer circumference of the grinding wheel 30 is formed in a stepped shape. Further, the location adjuster 50 brings the grinding wheel 30 into contact with the end face of the substrate 101 sequentially step by step from the grinding face 32b of the bottom step. Accordingly, even if the grinding face 32b of the bottom step is worn, the trimming processing can be continued with a grinding face different from the grinding face 32b. When the end face of the substrate 101 is thus ground by the grinding wheel 30 in a stepwise manner, the unprocessing time is unnecessary. This can improve the throughput of the trimming processing.

Furthermore, according to the present embodiment, the stepped shape of the grinding wheel 30 increases processing parts to be used in the processing of the substrate 101. Therefore, the life of the grinding wheel 30 can also be extended.

### Second Embodiment

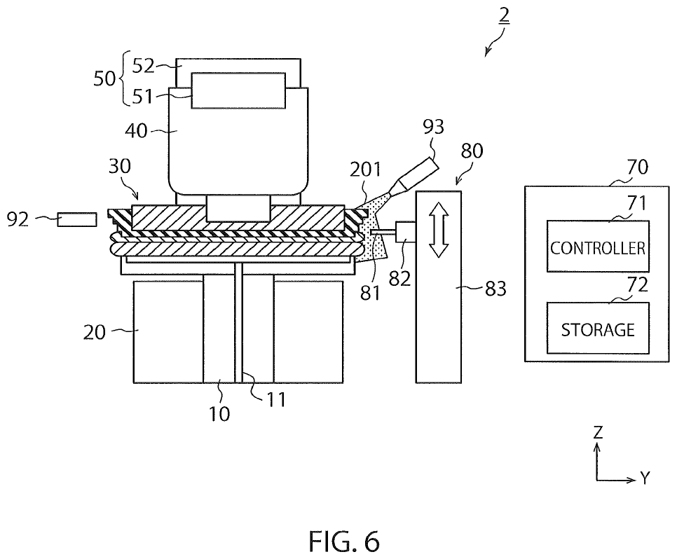

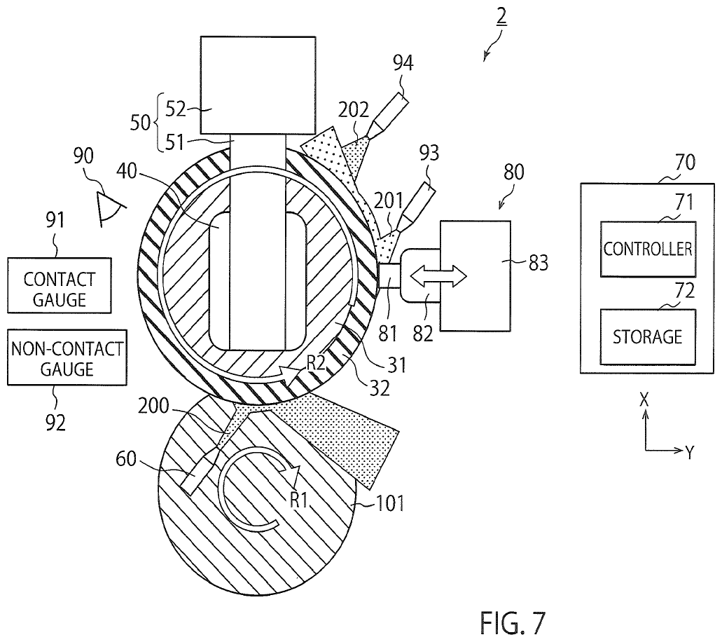

FIG. 6 is a schematic diagram illustrating a schematic configuration of a grinding apparatus according to a second embodiment. FIG. 7 is a top view of the grinding apparatus illustrated in FIG. 6. Constituent elements identical to those of the grinding apparatus 1 according to the first embodiment are denoted by like reference signs, and detailed explanations thereof are omitted.

As illustrated in FIGS. 6 and 7, a grinding apparatus 2 according to the present embodiment includes a dresser 80, a camera 90, a contact gauge 91, a non-contact gauge 92, a nozzle 93, and a two-fluid nozzle 94 in addition to the constituent elements of the grinding apparatus 1 according to the first embodiment.

The dresser 80 includes a dressing grinding stone 81, an arm 82, and a lift 83. The dressing grinding stone 81 corrects the shape of the grinding stone part 32 of the grinding wheel 30, which is unevenly worn due to grinding of the substrate 101. In the dressing grinding stone 81, diamond particles are coupled to each other with a bond material. The arm 82 and the lift 83 are a grinding stone holder that holds the dressing grinding stone 81 and also function as a dressing grinding stone driver that drives the dressing grinding stone 81 in the X direction, the Y direction, and the Z direction on the basis of control of the controller 71 of the terminal 70.

The camera 90 takes an image of the stepped grinding stone part 32 used last time in the trimming processing on the basis of control of the controller 71 of the terminal 70. The contact gauge 91 moves in the Y direction until being in contact with the grinding stone part 32 as a dressing target to measure location data related to the Y direction of the grinding stone part 32, on the basis of the control of the controller 71. The non-contact gauge 92 is an example of a measuring device that acquires data related to shape of the steps of the grinding stone part 32 as the dressing target in a non-contact manner on the basis of control of the controller 71. The shape data is acquired, for example, by laser scanning.

The nozzle 93 ejects pure water 201 toward a place where the grinding stone part 32 and the dressing grinding stone 81 are in contact with each other on the basis of control of the controller 71. The dressing place is cooled with the pure water 201. The two-fluid nozzle 94 is placed near the nozzle 93.

The two-fluid nozzle 94 ejects wash water 202 containing nitrogen and water on the basis of control of the controller 71. Grinding stone scraps generated by dressing of the grinding stone part 32 can be removed with the wash water 202.

A dressing operation of the grinding apparatus 2 described above is explained below.

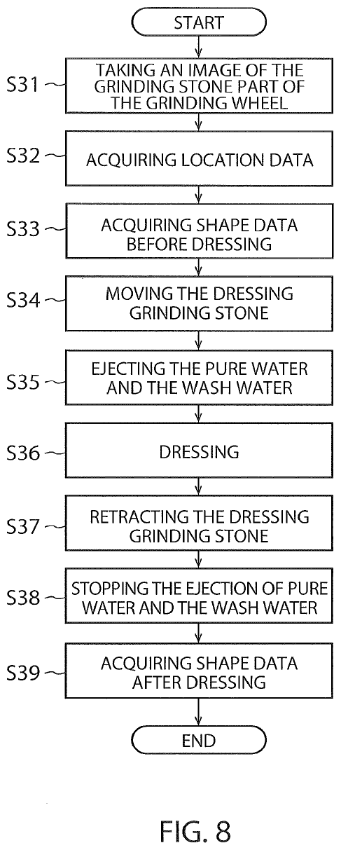

FIG. 8 is a flowchart for explaining a dressing operation of the grinding apparatus 2 according to the second embodiment. In the present embodiment, the dressing operation is performed at the same time as the trimming processing of the grinding operation.

In the grinding operation, the end face of the substrate 101 is first ground with the grinding face 32b of the bottom step of the grinding stone part 32 as explained in the first embodiment. The location adjuster 50 thereafter lowers the grinding wheel 30 in the Z direction and the grinding operation is continued with a grinding face of a step just above the grinding face 32b of the bottom step.

In the present embodiment, at the same time as the grinding operation is performed with the grinding face of the step just above the grinding face 32b of the bottom step, the camera 90 takes an image of the grinding stone part 32 of the grinding wheel 30 (Step S31). The controller 71 recognizes the rough location of the grinding face 32b of the bottom step of the grinding stone part 32, which is deformed due to the trimming processing, that is, the rough location of the dressing place on the basis of image data of the camera 90 stored in the storage 72.

Next, the contact gauge 91 horizontally moves until being in contact with the grinding stone part 32 to acquire location data of the grinding face 32b of the bottom step of the grinding stone part 32 related to the X direction and the Y direction (Step S32). The acquired location data is stored in the storage 72. The controller 71 recognizes the location of the grinding face 32b of the bottom step of the grinding stone part 32 as the dressing target on the basis of the location data stored in the storage 72. The contact gauge 91 retracts to the original location after having been brought into contact with the grinding stone part 32.

Next, the non-contact gauge 92 acquires shape data of the grinding face 32b of the bottom step before dressing (Step S33). The acquired shape data is stored in the storage 72. The controller 71 detects the amount of wear or the location related to the Z direction of the grinding face 32b of the bottom step on the basis of the shape data stored in the storage 72. The detected data is also stored in the storage 72.

Subsequently, the arm 82 and the lift 83 move the dressing grinding stone 81 to a position where the dressing grinding stone 81 is in contact with the grinding face 32b of the bottom step (Step S34).

Next, the nozzle 93 ejects the pure water 201 and the two-fluid nozzle 94 ejects the wash water 202 (Step S35). Accordingly, dressing to correct the shape of the grinding face 32b of the bottom step of the grinding stone part 32 is performed (Step S36). Details of the dressing are explained below.

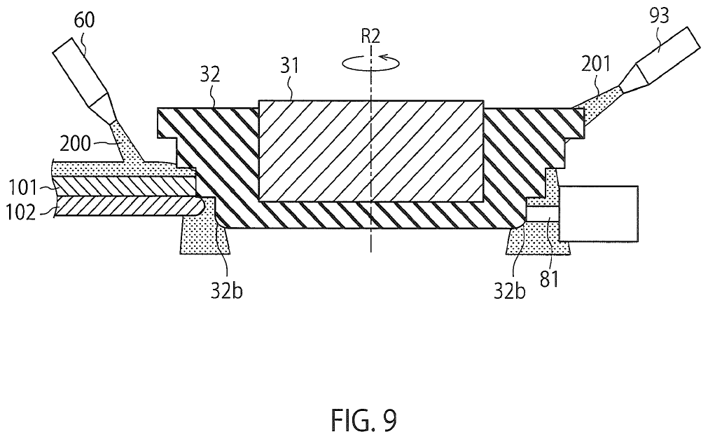

FIG. 9 is a diagram for explaining the dressing. In FIG. 9, dressing of the grinding face 32b of the bottom step of the grinding stone part 32 with the dressing grinding stone 81 is performed at the same time as the trimming of grinding the end face of the substrate 101 with the grinding face of a step just above the grinding face 32b of the bottom step.

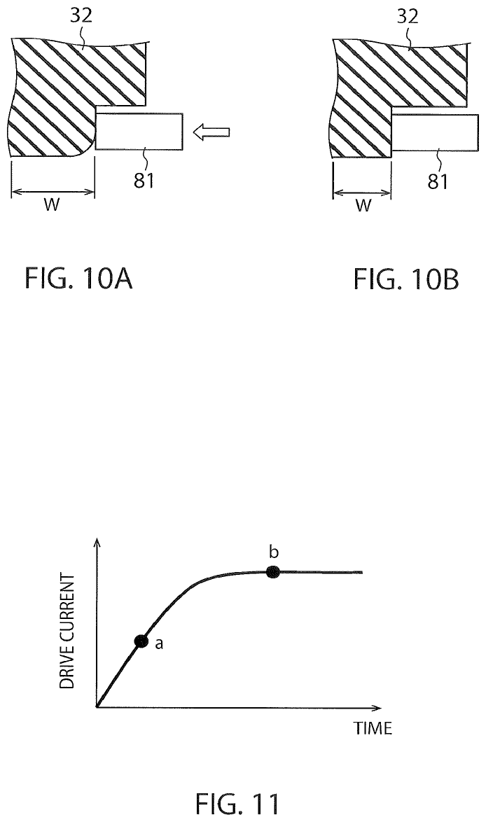

FIG. 10A is a diagram illustrating a state of the grinding stone part 32 at an initial stage of dressing. FIG. 10B is a diagram illustrating a state of the grinding stone part 32 at a last stage of the dressing. FIG. 11 is a graph illustrating changes of a drive current required to drive the dressing grinding stone 81. In FIG. 11, a point “a” corresponds to FIG. 10A and a point “b” corresponds to FIG. 10B.

At the initial stage of the dressing, the drive current increases because the dressing grinding stone 81 grinds a step face of the grinding stone part 32 as illustrated in FIG. 11. Thereafter, at the last stage of the dressing, the drive current stabilizes because the step face of the grinding stone part 32 is flat. The controller 71 of the terminal 70 detects an end point of the dressing on the basis of changes of the drive current.

When the end point of the dressing is detected, the arm 82 and the lift 83 retract the dressing grinding stone 81 from the grinding stone part 32 (Step S37). Next, the nozzle 93 stops the ejection of the pure water 201 and the two-fluid nozzle 94 stops the ejection of the wash water 202 (Step S38).

Subsequently, the non-contact gauge 92 acquires shape data of the grinding face 32b of the bottom step after the dressing (Step S39). The acquired shape data is stored in the storage 72. The controller 71 checks the dimension of the grinding stone part 32 after the dressing on the basis of the shape data stored in the storage 72. For example, the width W of the step of the grinding stone part 32 is narrowed by the dressing as illustrated in FIGS. 10A and 10B. Accordingly, the controller 71 calculates the width of the grinding face 32b of the bottom step after the dressing on the basis of the shape data. Dimension data indicating the calculated width W and the like is stored in the storage 72. The dimension data is used for alignment of the grinding face 32b of the bottom step with respect to the substrate 101 when second trimming is performed with the grinding face 32b of the bottom step of the grinding stone part 32.

The operations at Steps S31 to S39 described above are repeated step by step from the grinding face 32b of the bottom step to the grinding face 32a of the top step of the grinding stone part 32. When dressing is not finished yet at the end of trimming of one substrate 101, trimming of second and subsequent substrates 101 is continued until the end point of the dressing is detected.

According to the present embodiment described above, a grinding face of the grinding stone part 32 used for trimming of the substrate 101 is dressed during trimming of the next step. That is, while the substrate 101 is trimmed with one of two continuous grinding faces of the grinding stone part 32, the other grinding face is dressed. This enables trimming and dressing to be simultaneously performed and therefore the throughput can be further improved.

Although trimming of a substrate is performed first with the grinding face of the bottom step of the grinding wheel in the first and second embodiments, the trimming can be started with the grinding face of the top step or a different grinding face.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A grinding apparatus comprising:
a table to hold a substrate;
a grinding stone driver to be rotatable while holding a grinding stone; and
a location adjuster to adjust a relative location between the grinding stone driver and the table, wherein
the grinding stone has steps including a first grinding face and a second grinding face, and a first distance between a rotation center of the grinding stone driver and the first grinding face is different from a second distance between the rotation center and the second grinding face, and
the location adjuster adjusts the relative location from a first state in which the first grinding face is in contact with an end face of the substrate to a second state in which the second grinding face is in contact with the end face.

2. The apparatus of claim 1, further comprising:
a dressing grinding stone holder to hold a dressing grinding stone dressing the grinding stone;
a dressing grinding stone driver to drive the dressing grinding stone holder; and
a measuring device to acquire shape data of the first grinding face or the second grinding face after dressing.

3. The apparatus of claim 2, wherein the dressing grinding stone driver controls the dressing grinding stone holder to bring the first grinding face into contact with the dressing grinding stone when the second grinding face is in contact with the end face.

4. The apparatus of claim 2, further comprising a controller to detect an end point of dressing with the dressing grinding stone on a basis of changes of a drive current required to drive the dressing grinding stone.

5. The apparatus of claim 1, wherein the second distance is larger than the first distance.

6. A grinding method of grinding an end face of a substrate with a grinding stone which rotates and having steps including a first grinding face and a second grinding face, where a distance between a rotation center and the first grinding face is different from a distance between the rotation center and the second grinding face, the method comprising:
bringing the first grinding face into contact with the end face; and
bringing the second grinding face into contact with the end face after bringing the first grinding face into contact with the end face.

7. The method of claim 6, comprising:
dressing the first grinding face with a dressing grinding stone after grinding the end face with the first grinding face;
acquiring shape data of the first grinding face after dressing;
dressing the second grinding face with the dressing grinding stone after grinding the end face with the second grinding face; and
acquiring shape data of the second grinding face after dressing.

8. The method of claim 7, comprising dressing the first grinding face with the dressing grinding stone while grinding the end face with the second grinding face.

9. The method of claim 7, comprising detecting an end point of dressing with the dressing grinding stone on a basis of changes of a drive current required to drive the dressing grinding stone.
